(19) United States
(12) Patent Application Publication
(10) Pub. No.: US 2015/0137900 A1
(43) Pub. Date: May 21, 2015

(54) RESONATOR ELEMENT, RESONATOR, OSCILLATOR, ELECTRONIC DEVICE, AND MOBILE OBJECT

(71) Applicant: SEIKO EPSON CORPOATION, Tokyo (JP)

(72) Inventor: Akinori YAMADA, Ina-shi (JP)

(21) Appl. No.: 14/540,776

(22) Filed: Nov. 13, 2014

(30) Foreign Application Priority Data
Nov. 16, 2013 (JP) 2013-237474

(51) Int. Cl. H03H 9/215; H03B 5/32

(52) U.S. Cl. CPC H03H 9/215; H03B 5/32
USPC 331/156; 310/370

(57) ABSTRACT

A resonator element includes a base section, a pair of vibrating arms extending from the base section, and a holding arm extending from the base section between the pair of vibrating arms. The vibrating arms include arm sections extending from the base section and hammerheads provided at the distal end sections of the arm sections. When the mass of the vibrating arms is represented as M1 and the mass of the holding arm is represented as M2, a relation of M1>M2 is satisfied.

### BACKGROUND

1. Technical Field

The present invention relates to a resonator element, a resonator, an oscillator, an electronic device, and a mobile object.

2. Related Art

As a vibrating device such as a quartz oscillator, a vibrating device including a resonator element of a tuning fork type is known (see, for example, JP-A-2003-163568 (Patent Literature 1)).

For example, a resonator described in Patent Literature 1 includes a tuning-fork portion including two arms joined by a base. In the base, between the two arms, a center arm arranged in parallel to the arms is attached. In the resonator, for the purpose of realizing satisfactory decoupling (reducing vibration leakage), the mass of the center arm is set larger than the mass of the arms in the tuning-fork portion.

However, the resonator element having such a relation of mass is poorly balanced when being mounted on a package and tends to be oblique to a mounting surface of the package during the mounting. Such a problem leads to deterioration of yield during manufacturing, complication of a manufacturing process, deterioration in reliability of a product, and the like.

### SUMMARY

An advantage of some aspects of the invention is to provide a resonator element that can improve stability when mounted and provide a resonator, an oscillator, an electronic device, and a mobile object including the resonator element and having excellent reliability.

The invention can be implemented as the following forms or application examples.

### APPLICATION EXAMPLE 1

A resonator element according to this application example includes: a base section; a pair of vibrating arms extending from the base section along a first direction and arranged side by side along a second direction, which crosses the first direction, in plan view; and a holding arm arranged between the pair of vibrating arras and extending from the base section along the first direction in plan view. When the mass of each of the pair of vibrating arms is represented as M1 and the mass of the holding arm is represented as M2, a relation of M1>M2 is satisfied.

With the resonator element, since the mass of both ends of the resonator element in the second direction is large, when the resonator element is mounted with the holding arm fixed to a target object, the resonator element warps and the center of gravity of the resonator element moves to the target object side (the lower side) with respect to a fulcrum by the fixing. As a result, it is possible to improve stability of the resonator element.

### APPLICATION EXAMPLE 2

In the resonator element according to the application example described above, it is preferable that the vibrating arm includes a weight section; and an arm section arranged between the base section and the weight section in plan view, and when the mass of the weight section is represented as M3, a relation of M2<2×M3 is satisfied.

With this configuration, a warp of the resonator element for displacing an end of the resonator element in the first direction (in particular, an end on the weight section side) to the lower side easily occurs. Therefore, when the resonator element is mounted with the holding arm fixed to the target object, it is possible to further improve the stability of the resonator element.

### APPLICATION EXAMPLE 3

In the resonator element according to the application example described above, it is preferable that a relation of M2<M3 is satisfied.

With this configuration, the warp of the resonator element for displacing the end of the resonator element in the first direction to the lower side (the target object side) more easily occurs.

### APPLICATION EXAMPLE 4

In the resonator element according to the application example described above, it is preferable that, when the mass of the base section is represented as M4, a relation of M2<M4 is satisfied.

With this configuration, the warp of the resonator element for displacing the end of the resonator element in the first direction (in particular, an end on the base section side) to the lower side (the target object side) easily occurs. Therefore, when the resonator element is mounted with the holding arm fixed to the target object, it is possible to further improve the stability of the resonator element.

### APPLICATION EXAMPLE 5

In the resonator element according to the application example described above, it is preferable that, when the mass of the arm section is represented as M5, a relation of M3>M5 is satisfied.

With this configuration, the warp of the resonator element for displacing the end of the resonator element in the first direction (in particular, the end on the weight section side) to the lower side (the target object side) easily occurs because of a warp of the arm section of the vibrating arm. Therefore, when the resonator element is mounted with the holding arm fixed to the target object, it is possible to further improve the stability of the resonator element.

### APPLICATION EXAMPLE 6

In the resonator element according to the application example described above, it is preferable that a fixed section attached to a target object is provided in the holding arm, and the fixed section overlaps the center of gravity of a structure including the base section, the vibrating arm, and the holding arm in plan view.

With this configuration, when the resonator element is mounted with the holding arm fixed to the target object, it is possible to further improve the stability of the resonator element.

### APPLICATION EXAMPLE 7

In the resonator element according to the application example described above, it is preferable that a distal end of the holding arm on the opposite side of the base section side is located further on the base section side than the weight section.

With this configuration, it is possible to arrange the holding arm efficiently using a space between the arm sections of the pair of vibrating arms. Since the holding arm is absent between the weight sections of the pair of vibrating arms, it is possible to reduce the distance between the vibrating arms. As a result, it is possible to attain a reduction in the size of the resonator element.

### APPLICATION EXAMPLE 8

In the resonator element according to the application example described above, it is preferable that the holding arm includes: a main body section including a fixed section attached to a target object; and a connecting section that connects the main body section and the base section and has width along the second direction smaller than the width of the main body section.

With this configuration, a warp of the resonator element for displacing an end of the resonator element in the first direction (in particular, an end on the base section side) to the lower side (the target object side) easily occurs because of a warp of the holding arm. Therefore, when the resonator element is mounted with the holding arm fixed to the target object, it is possible to further improve the stability of the resonator element.

### APPLICATION EXAMPLE 9

In the resonator element according to the application example described above, it is preferable that a groove is provided along the first direction on at least one of a first principal plane and a second principal plane of the arm section that are in a front-back relation each other.

With this con figuration, a warp of the resonator element for displacing an end of the resonator element in the first direction (in particular, an end on the weight section side) to the lower side (the target object side) easily occurs because of a warp of the arm section of the vibrating arm. Therefore, when the resonator element is mounted with the holding arm fixed to the target object, it is possible to further improve the stability of the resonator element. Further, it is possible to reduce a thermoelastic loss and increase a Q value.

### APPLICATION EXAMPLE 10

A resonator according to this application example includes: the resonator element according to the application example described above; and a package in which the resonator element is housed.

With this configuration, it is possible to provide the resonator having excellent reliability.

### APPLICATION EXAMPLE 11

An oscillator according to this application example includes: the resonator element according to the application example described above; and an oscillation circuit electrically connected to the resonator element.

With this configuration, it is possible to provide the oscillator having excellent reliability.

### APPLICATION EXAMPLE 12

An electronic device according to this application example includes the resonator element according to the application example described above.

With this configuration, it is possible to provide the electronic device having excellent reliability.

### APPLICATION EXAMPLE 13

A mobile object according to this application example includes the resonator element according to the application example described above.

With this configuration, it is possible to provide the mobile object having excellent reliability.

### BRIEF DESCRIPTION OF THE DRAWINGS

The invention will be described with reference to the accompanying drawings, wherein like numbers reference like elements.

FIG. 1 is a plan view showing a resonator element according to a first embodiment of the invention.

FIG. 2 is a sectional view taken along line A-A in FIG. 1.

FIGS. 3A and 3B are plan views for explaining a principle of vibration leakage suppression.

FIGS. 4A and 4B are diagrams of a simplified model of the resonator element for explaining stability during mounting, wherein FIG. 4A is a diagram showing a resonator element in the past and FIG. 4B is a diagram showing the resonator element according to the first embodiment.

FIG. 5 is a perspective view showing a state in which the gravity is applied to the resonator element shown in FIG. 1.

FIG. 6 is a diagram for explaining the dimensions and the masses of sections of the resonator element.

FIG. 7 is a plan view showing a resonator element according to a second embodiment of the invention.

FIG. 8 is a diagram showing an example of a resonator according to the first embodiment.

FIG. 9 is a diagram showing an example of an oscillator according to the first embodiment.

FIG. 10 is a perspective view showing the configuration of a personal computer of a mobile type (or a notebook type), which is an example of an electronic device according to the first embodiment.

FIG. 11 is a perspective view showing the configuration of a cellular phone (including a PHS), which is a second example of the electronic device according to the first embodiment.

FIG. 12 is a perspective view showing the configuration of a digital still camera, which is a third example of the electronic device according to the first embodiment.

FIG. 13 is a perspective view showing the configuration of an automobile, which is an example of a mobile object according to the first embodiment.

### DESCRIPTION OF EXEMPLARY EMBODIMENTS

Embodiments of the invention are explained in detail below with reference to the accompanying drawings.

### 1. Resonator Element

### First Embodiment

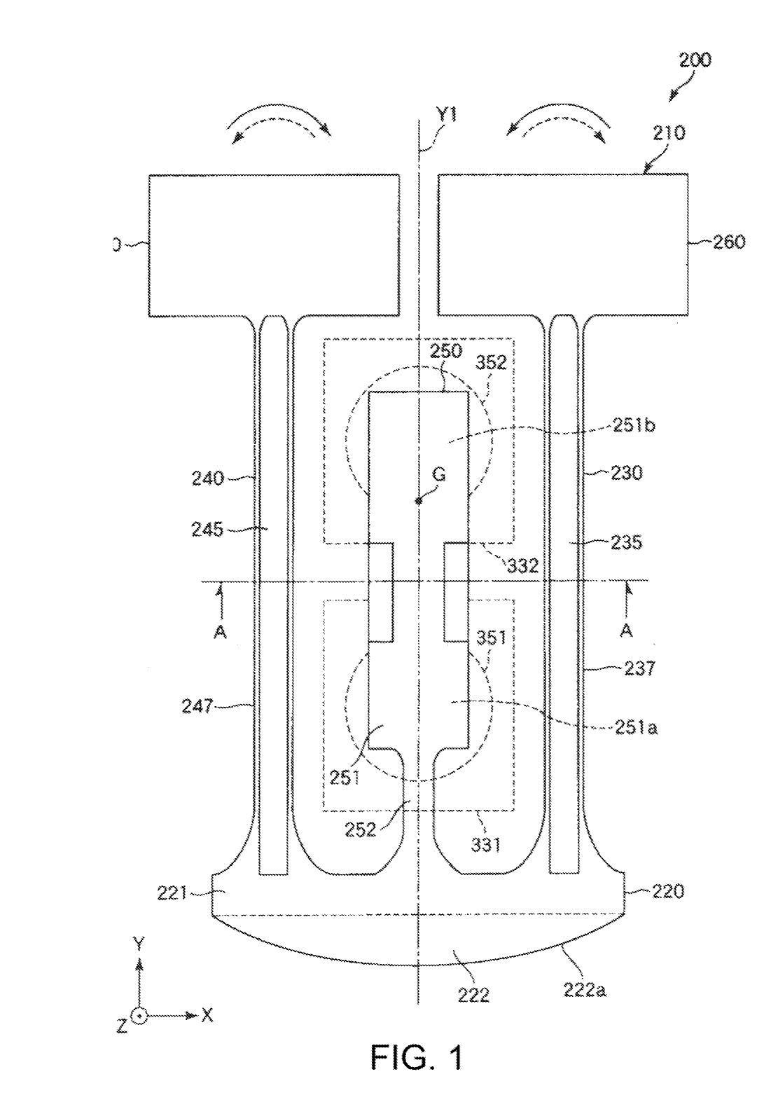

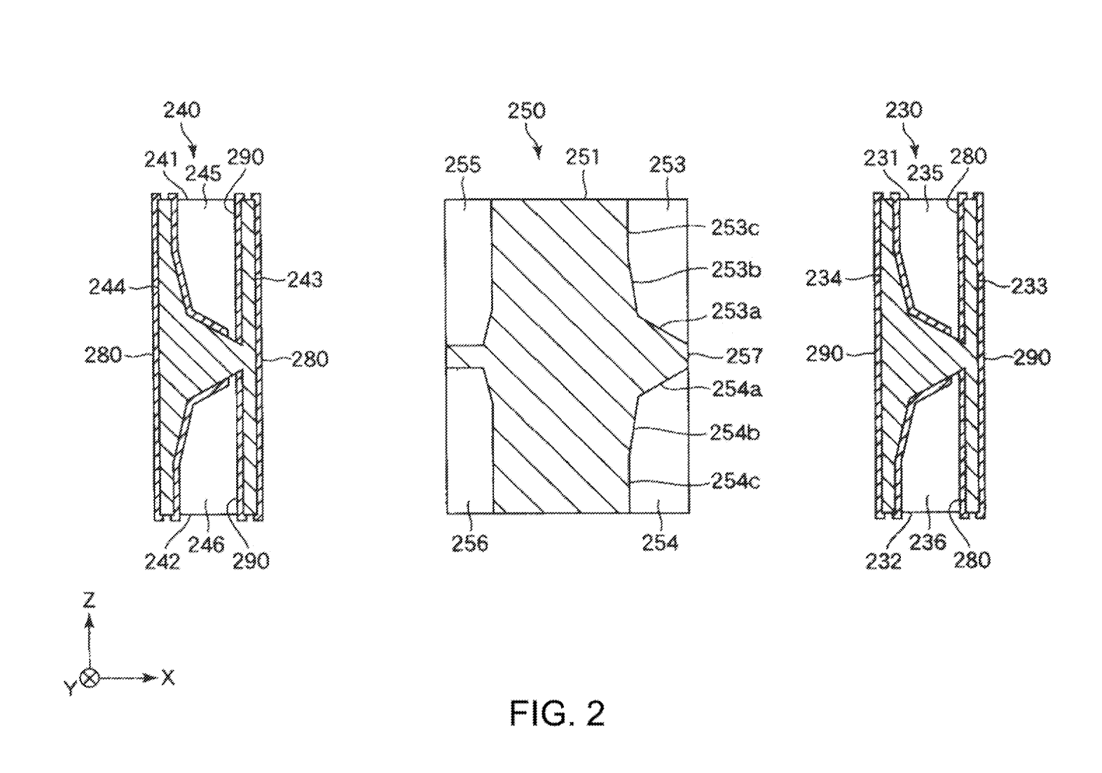

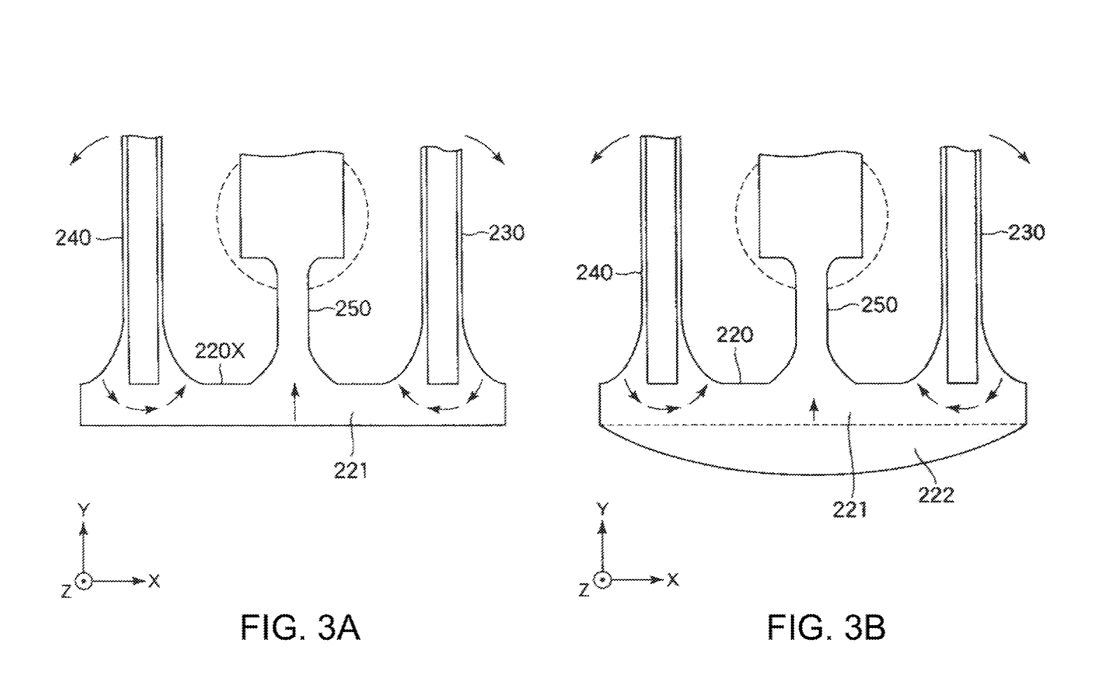

FIG. 1 is a plan view showing a resonator element according to a first embodiment of the invention. FIG. 2 is a sectional view taken along line A-A in FIG. 1. FIGS. 3A and 3B are plan views for explaining a principle of vibration leakage suppression.

Note that, in the figures, for convenience of explanation, an X axis, a Y axis, and a Z axis are shown as three axes orthogonal to one another. In the following explanation, a direction parallel to the X axis (a second direction) is referred to as “X-axis direction, a direction parallel to the Y axis (a first direction) is referred to as “Y-axis direction”, and a direction parallel to the Z axis (a third direction) is referred to as “Z-axis direction”, Distal end sides of arrows of the X axis, the Y axis, and the Z axis shown in the figures are referred to as “+ (plus)” and proximal end sides of the arrows are referred to as “− (minus)”. In the following explanation, for convenience of explanation, a plan view in view from the Z-axis direction is simply referred to as “plan view” as well. For convenience of explanation, the upper side in FIG. 1 (the +Z-axis direction side) is referred to as “upper” as well and the lower side (the −Z-axis direction side) is referred to as “lower” as well.

A resonator element 200 shown in FIGS. 1 and 2 includes a vibration substrate 210 and a first driving electrode 280 and a second driving electrode 290 (see FIG. 2) formed on the vibration substrate 210.

The vibration substrate 210 is configured by, for example, quartz, in particular, a Z-cut quartz plate. Consequently, the resonator element 200 can display an excellent vibration characteristic. The Z-cut quartz plate is a quarts plate having a thickness direction in a Z axis (an optical axis) of quartz. The Z axis preferably coincides with the thickness direction of the vibration substrate 210. From the viewpoint of reducing a frequency temperature change in the vicinity of the normal temperature, the Z axis is slightly tilted (e.g., about less than 15°) with respect to the thickness direction.

The vibration substrate 210 includes a base section 220, two vibrating arms 230 and 240 projecting from the base section 220 to the +Y-axis direction and provided side by side in the X-axis direction, and a holding arm 250 projecting from the base section 220 to the +Y-axis direction and located between the two vibrating arms 230 and 240. The vibration substrate 210 is formed to be symmetrical with respect to an axis of symmetry Y1 parallel to the Y axis.

The base section 220 is formed in a substantially tabular shape expanding along an XY plane, which includes the X axis and the Y axis, and having a thickness direction in the Z-axis direction. The base section 220 includes a main body section 221 that supports and couples arms 230, 240, and 250 and a reduced width section 222 (a first reduced width section) that reduces vibration leakage.

As shown in FIG. 1, the width (the length along the X-axis direction) of the main body section 221 is substantially fixed along the Y-axis direction. That is, the main body section 221 has a substantially rectangular plan view shape. The reduced width section 222 is connected to the outer edge on the −Y-axis direction side of the main body section 221. That is, the reduced width section 222 is provided on the opposite side of the arms 230, 240, and 250 via the main body section 221.

The contour of the reduced width section 222 is formed by an arc section 222a in an arcuate shape symmetrical with respect to the axis of symmetry Y1. Both ends of the arc section 222a are connected to corners in the −Y-axis direction side of the main body section 221.

A curvature radius of the arc section 222a is fixed over the entire area of the arc section 222a. Note that the curvature radius of the arc section 222a is not limited to be fixed and, for example, may gradually increase toward the −Y-axis direction or may gradually decrease oppositely.

The outer edge of the reduced width section 222 is not limited to a carved line shape like the arc section 222a and may be formed by a linear inclined section or a stair-like step having a plurality of level differences. When the vibration substrate 210 including the vibrating arms 230 and 240 and the base section 220 is formed by wet-etching a quarts substrate, a crystal surface of quarts appears in the contour of the vibration substrate 210. Therefore, when viewed microscopically, the arc section 222a is considered to be an aggregate of short linear portions. The shape of the arc section 222a in such a case is included in the “arcuate shape”. In this case, an arc may be formed further on the inner side (the main body section 221 side) than the arc section 222a formed as the aggregate of the short linear portions by additionally applying wet etching to a degree for not exposing the crystal surface.

The width along the X-axis direction of the reduced width section 222 gradually decreases toward a direction side away from the base section 220 along the axis of symmetry Y1 (an imaginary center line) that is parallel to the Y axis and passes the center of the base section 220.

Consequently, it is possible to effectively reduce deformation of the base section 220 involved in bending vibration of the pair of vibrating arms 230 and 240 repeating approach and separation each other substantially in a plane. As a result, even if the length along the Y-axis direction of the base section 220 is reduced, it is possible to reduce the deformation of the base section 220 involved in the bending vibration of the pair of vibrating arms 230 and 240 approaching and separating each other. It is possible to reduce vibration leakage from the base section 220 to the outside. Note that a principle of the vibration leakage reduction by the reduced width section 222 is explained in detail below.

Maximum width (length at a projecting direction proximal end) of the reduced width section 222 is substantially equal to the width of the main body section 221. The reduced width section 222 is continuously formed to the end (the corner) on the −Y-axis direction side of the main body section 221 without a level difference. Consequently, in the reduced, width section 222 and at the end (the corner) on the −Y-axis direction side of the main body section 221, it is possible to reduce an increase in a temperature change that occurs because of concentration of distortion during bending vibration and reduce an increase in a heat flow. Therefore, it is possible to reduce an increase in a thermoelastic loss and deterioration in a Q value.

The holding arm 250 extends from the base section 220 in the +Y-axis direction and is located between the vibrating arms 230 and 240.

The holding arm 250 includes a main body section 251 and a connecting section 252 that connects the main body section 251 and the base section 220. The holding arm 250 is fixed to a package, whereby the resonator element 200 is set in the package. The setting of the resonator element 200 is explained in detail below.

On the lower surface of the holding arm 250, two electrode pads (not shown in the figure) are provided to correspond to two connection electrodes 331 and 332 explained below. In the holding arm 250, cutout sections 253, 254, 255, and 256 located between the two electrode pads in plan view are provided.

The cutout section 253 is opened to the upper surface and the side surface of the +X-axis direction side of the holding arm 250. The cutout section 254 is opened to the lower surface and the side surface on the +X-axis direction side of the holding arm 250. The cutout section 255 is opened to the upper surface and the side surface on the −X-axis direction side of the holding arm 250. The cutout section 256 is opened to the lower surface and the side surface on the −X-axis direction side of the holding arm 250.

The cutout sections 253 and 254 prevent short circuit between two electrode pads having different potentials each other due to a side surface electrode (not shown in the figure) remaining on the side surface of the holding arm 250 when an electrode including the first driving electrode 280, the second driving electrode 290, and the electrode pad is formed. On the other hand, the cutout sections 255 and 256 prevent asymmetry of the shape of the holding arm 250 caused by the provision of the cutout sections 253 and 254 in the holding arm 250.

It is extremely difficult to completely remove the side surface electrode, which is formed on the side surface substantially orthogonal to the principal plane of the holding arm 250, with a normal exposing device without using an oblique exposure device or the like in a photolithography process used when the electrode including the first driving electrode 280, the second driving electrode 290, and the electrode pad is formed. This is because the side surface of the holding arm 250 covered with a resist film formed in the photolithography process is not completely exposed to light. Up to about 20 μm in the plate thickness direction from the principal plane of the holding arm 250, the side surface can be exposed to light and the side surface electrode can be removed by the normal exposing device. However, light hardly reaches a part in the center in the plate thickness direction and the part cannot be exposed to light. Therefore, the side surface electrode remains and short-circuit between the two electrode pads occurs.

Therefore, as shown in FIG. 2, in the cutout section 253, first inclined surfaces 253a and 253b connected to the upper surface of the holding arm 250 via a surface 253c are provided. Similarly, second inclined surfaces 254a and 254b are provided in the cutout section 254 connected to the lower surf ace of the holding arm 250 via a surf ace 254c. Consequently, by setting the dimension in the Z-axis direction of the surfaces 253c and 254c substantially orthogonal to the principal plane of the holding arm 250 to 20 μm or less, the surfaces 253c and 254c can be exposed to light by the normal exposing device. Similarly, a side surface 257 that connects the first inclined surface 253a and the second inclined surface 254a is also orthogonal to the principal plane of the holding arm 250. By setting the dimension in the Z-axis direction of the side surface 257 to 20 μm or less, the side surface 257 can be exposed to light by the normal exposing device. In this way, it is possible to prevent short circuit between the two electrode pads.

The formation of the cutout sections 253 and 254 can be performed by wet-etching the vibration substrate 210 formed by the Z-cut quartz plate. It is possible to reduce an etching time by simultaneously etching the front and the back of the substrate.

In general, quarts has etching anisotropy. Therefore, an etching rate is different for each direction of a crystal axis. Therefore, when the Z-cut quarts plate is used, if a crystal X axis of the quartz is the X axis in FIG. 2, a crystal Y axis of the quarts is the Y axis in FIG. 2, and if a crystal Z axis of the quartz is the Z axis in FIG. 2, the shapes of side surfaces 233, 234, 243, and 244 substantially orthogonal to the X-axis direction of the vibrating arms 230 and 240 shown in FIG. 2 are different from one another. That is, the shapes of the side surfaces 233 and 243 in the +X-axis direction and the side surfaces 234 and 244 in the −X-axis direction are different. Whereas the shape of the side surfaces 234 and 244 in the −X-axis direction is a substantially flat shape, as the shape of the side surfaces 233 and 243 in the +X-axis direction, a convex inclined section like a triangular pyramid-shaped protrusion section, which decreases in size as the wet-etching time is longer, is formed in the center in the plate thickness direction (the Z-axis direction).

In particular, in an XZ plane of the vibrating arms 230 and 240, the side surfaces 233 and 243 in the +X-axis direction include two inclined surfaces, i.e., an inclined surface substantially orthogonal to the principal planes of the vibrating arms 230 and 240 and an inclined surface on which the triangular pyramid-shaped protrusion section is formed. Note that, when the external shape of the resonator element 200 is formed, in order to prevent vibration leakage caused by asymmetry of the sectional shape of the vibrating arms 230 and 240, long-time wet etching is applied to secure symmetry of the sectional shape of the vibrating arms 230 and 240.

On the other hand, in the cutout sections 253 and 254, as shown in FIG. 2, the first and second inclined surfaces 253a, 253b, 254a, and 254b extending in the +X-axis direction generated by the etching anisotropy of quartz and the surfaces 253c and 254c substantially orthogonal to the principal plane of the holding arm 250 can be intentionally formed by reducing the wet-etching time. In particular, the formation of the cutout sections 253 and 254 is efficiently performed if the formation is performed together with the formation of grooves 235, 236, 245, and 246.

Note that the dimensions in the Z-axis direction of the side surface 257 and the surfaces 253c and 254c in an area where the cutout sections 253 and 254 are provided are respectively desirably equal to or smaller than 20 μm and preferably equal to or smaller than 10 μm. The dimension in the Y-axis direction of the cutout sections 253 and 254 is desirably 5 to 500 μm because the cutout sections 253 and 254 can be reduced in size while having length of an opening section at least necessary for etching to proceed and is preferably 20 to 100 μm at which the etching easily proceeds and a further reduction in size can be attained. Further, the dimension in the X-axis direction of the cutouts 253 and 254 is desirably 5 to 300 μm because the cutouts 253 and 254 can be reduced in size while having length of an opening section at least necessary for the etching to proceed and is preferably 10 to 50 μm at which the etching easily proceeds and a further reduction in size can be attained.

The vibrating arms 230 and 240 are provided side by side in the X-axis direction at a predetermined interval distance and respectively project from the base section 220 to the +Y-axis direction. The vibrating arms 230 and 240 respectively include arm sections 237 and 247 extending from the base section 220 and hammerheads 260 and 270 functioning as weight sections provided at the distal end sections of the arm sections 237 and 247 and having width larger than the width of the arm sections 237 and 247. By providing the hammerheads 260 and 270, it is possible to attain a reduction in the slue of the resonator element 200 and reduce a frequency of bending vibration of the vibrating arms 230 and 240.

In the vibrating arm 230, a bottomed groove 235 opened to one principal plane 231 and a bottomed groove 236 opened to the other principal plane 232 are formed. Similarly, in the vibrating arm 240, a bottomed groove 245 opened to one principal plane 241 and a bottomed groove 246 opened to the other principal plane 242 are formed. The grooves 235, 236, 245, and 246 are provided to extend in the Y-axis direction and formed in the same shape as one another. Therefore, the vibrating arms 230 and 240 are formed in a substantially “H”-like cross sectional shape. By forming the grooves 235, 236, 245, and 246, heat generated by bending vibration less easily spreads (thermally conducts). In an adiabatic area, which is an area where a bending vibration frequency (a mechanical bending vibration frequency) f is larger than a thermal relaxation frequency f0 (f>f0), it is possible to suppress a thermoelastic loss. Note that the grooves 235, 236, 245, and 246 only have to be provided according to necessity and may be omitted.

As shown in FIG. 2, in the vibrating arm 230, the first driving electrode 280 and the second driving electrode 290 are formed. The first driving electrode 280 is formed on the inner surfaces of the grooves 235 and 236. The second driving electrode 290 is formed on the side surfaces 233 and 234. Similarly, in the vibrating arm 240, the first driving electrode 280 and the second driving electrode 290 are formed. The first driving electrode 280 is formed on the side surfaces 243 and 244. The second driving electrode 290 is formed on the inner surfaces of the grooves 245 and 246. When an alternating voltage is applied between the first and second driving electrodes 280 and 290, the vibrating arms 230 and 240 vibrate at a predetermined frequency in an in-plane direction (an XY plane direction) to repeat approach and separation each other. In this embodiment, like the cutout sections 253 and 254, the grooves 235 and 236 have inclined surfaces. A part of the first driving electrode 280 is chipped in the bottom sections of the grooves 235 and 236. Consequently, it is possible to prevent a flow of heat in the X-axis direction in the vibrating arm 230 from increasing. As a result, it is possible to prevent a thermoelastic loss from increasing. Note that, the second driving electrode 290 in the grooves 245 and 246 is the same as the first driving electrode 280 in the grooves 235 and 236.

A constituent material of the first driving electrode 280 and the second driving electrode 290 is not particularly limited. Metal materials such as gold (Au), a gold alloy, platinum (Pt), aluminum (Al), an aluminum alloy, silver (Ag), a silver alloy, chromium (Cr), a chromium alloy, copper (Cu), molybdenum (Mo), niobium (Nb), tungsten (W), iron (Fe), titanium (Ti), cobalt (Co), zinc (Zn), and zirconium (Zr) and conductive materials such as indium tin oxide (ITO) can be used.

Note that, although not shown in the figure, the first driving electrode 280 and the second driving electrode 290 are drawn out to the holding arm 250 via the base section 220. For example, conduction to a connection electrode formed in a package 300 described below is attained by the holding arm 250.

The configuration of the resonator element 200 is explained below.

### Principle of the Vibration Leakage Suppression by the Reduced Width Section

The principle of the vibration leakage suppression by the reduced width section 222 is explained. Note that, in the following explanation, to simplify the explanation, it is assumed that the shape of the resonator element is symmetrical with respect to a predetermined axis parallel to the Y axis.

First, a base section 220X not provided with the reduced width section 222 as shown in FIG. 3A is explained.

When the vibrating arms 230 and 240 are bending-deformed to separate from each other, in the main body section 221 near a part to which the vibrating arm 230 is connected, displacement similar to a clockwise rotary motion occurs as indicated by arrows. On the other hand, in the main body section 221 near a part to which the vibrating arm 240 is connected, displacement similar to a counterclockwise rotary motion occurs as indicated by arrows. However, these kinds of displacement are not motions exactly considered to be the rotary motions. Therefore, for convenience, the kinds of displacement are expressed as being similar to the rotary motions.

Since X-axis direction components of these kinds of displacement are directed to opposite directions each other, the X-axis direction components are offset in the center in the X-axis direction of the main body section 221. Displacement in the +Y-axis direction remains. Note that, although displacement in the Z-axis direction also remains exactly, the displacement is omitted here.

The main body section 221 is bending-deformed to displace the center in the X-axis direction to the +Y-axis direction. When an adhesive is formed in the center in the Y-axis direction of the main body section 221 having the displacement in the +Y-axis direction and the main body section 221 is fixed to the package via the adhesive, elastic energy accompanying the +Y-axis direction displacement leaks to the outside via the adhesive. This is a loss called vibration leakage and causes deterioration in the Q value (as a result, deteriorates an IC value).

On the other hand, in the base section 220 provided with the reduced width section 222 as shown in FIG. 3B, since the reduced width section 222 has a convex contour, the kinds of displacement similar to the rotary motions get caught each other in the reduced width section 222.

That is, in the center in the X-axis direction of the reduced width section 222, as in the center in the X-axis direction of the main body section 221, the displacement in the X-axis direction is offset and, at the same time, the displacement in the Y-axis direction is suppressed.

Further, since the contour of the reduced width section 222 is convex, the displacement in the +Y-axis direction about to occur in the main body section 221 is also suppressed. As a result, the displacement in the +Y-axis direction in the center in the X-axis direction of the base section 220 provided with the reduced width section 222 is much small compared with the base section 220X not provided with the reduced width section 222. That is, it is possible to obtain the resonator element 200 having small vibration leakage.

As explained above, it is possible to suppress the vibration leakage with the reduced width section 222.

### Setting of the Vibration Piece

Setting of the resonator element 200 is explained with reference to FIG. 2 and FIGS. 4A to 6.

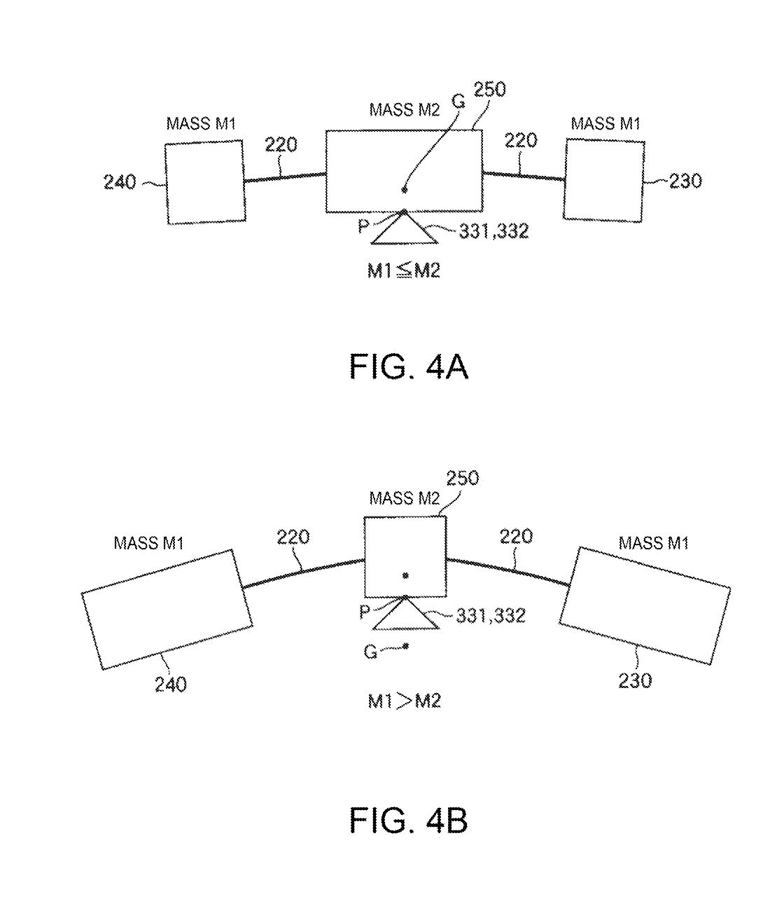

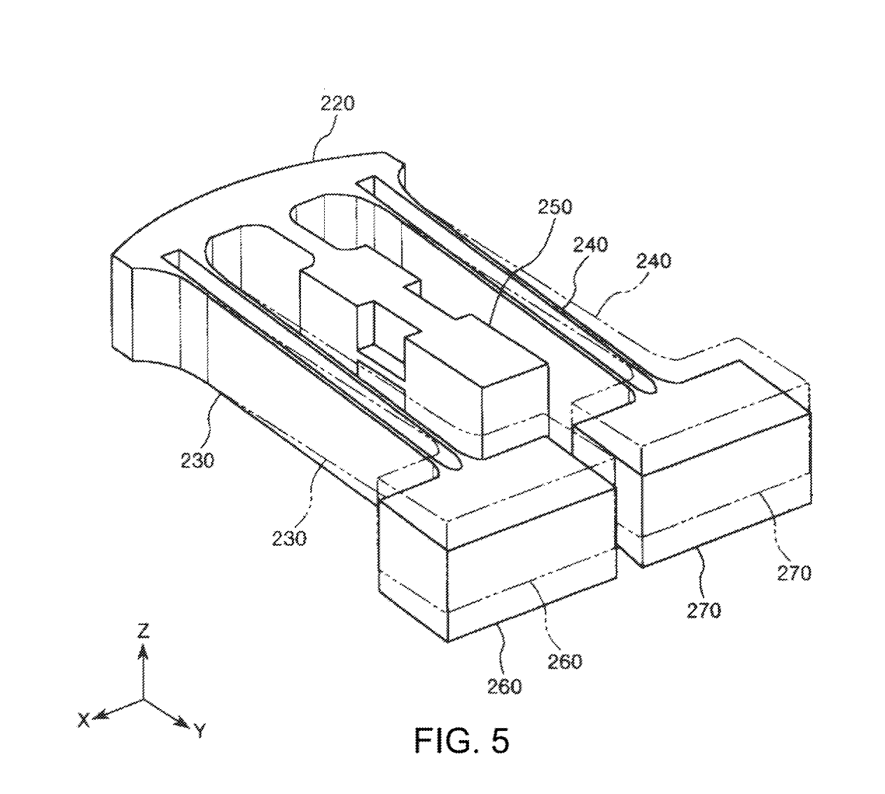

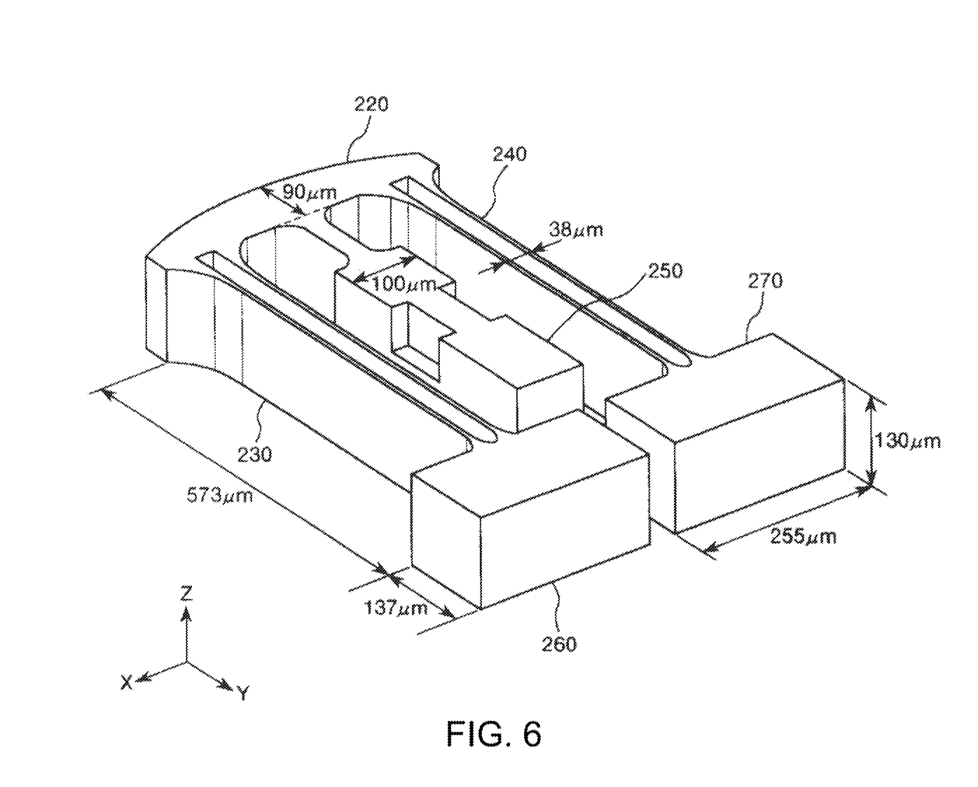

FIGS. 4A and 4B are diagrams of a simplified model of the resonator element for explaining stability during mounting, wherein FIG. 4A is a diagram showing a resonator element in the past and FIG. 4B is a diagram showing the resonator element according to the first embodiment. FIG. 5 is a perspective view showing a state in which the gravity is applied to the resonator element shown in FIG. 1. FIG. 6 is a diagram for explaining the dimensions and the masses of the sections of the resonator element.

As explained above, the holding arm 250 extends from the base section 220 from which the vibrating arms 230 and 240 extend. The holding arm 250 (more specifically, the main body section 251) is attached to the package, whereby the resonator element 200 is set in the package. Note that, in FIG. 1, the two connection electrodes 331 and 332 included in a not-shown package and conductive adhesives 351 and 352 for attaching the holding arm 250 to the two connection electrodes 331 and 332 are indicated by broken lines. Portions bonded to the conductive adhesives 351 and 352 are fixed sections 251a and 251b.

The holding arm 250 extends, between the pair of vibrating arms 230 and 240, from the base section 220 to a side same as the side to which the vibrating arms 230 and 240 extend. As explained above, the vibrating arms 230 and 240 include the arm sections 237 and 247 extending from the base section 220 and the hammerheads 260 and 270 functioning as the weight sections provided at the distal end sections of the arm sections 237 and 247 and having width larger than the width of the arm sections 237 and 247.

In the resonator element 200 including the holding arm 250 and the vibrating arms 230 and 240, when the mass of the vibrating arms 230 and 240 (the mass of one vibrating arm 230 or 240) is represented as M1 and the mass of the holding arm 250 is represented as M2, if the resonator element 200 has a relation of M1≦M2, as shown in FIG. 4A, since the mass of both ends in the X-axis direction (the vibrating arms 230 and 240) of the resonator element 200 is small, the resonator element 200 hardly warps when the resonator element 200 is mounted with the holding arm 250 fixed to the package (a target object). A center of gravity G of the resonator element 200 is located within the holding arm 250. Therefore, the center of gravity G of the resonator element 200 is located on the opposite side (the upper side) of the target object with respect to a fulcrum P by the fixing to make the resonator element 200 unstable. As a result, the resonator element 200 tends to be oblique to a setting surface of the package when mounted, leading to deterioration in yield during manufacturing, complication of a manufacturing process, deterioration of reliability of a product, and the like.

Therefore, the resonator element 200 satisfies a relation of M1>M2. Consequently, as shown in FIGS. 4B and 5, the mass of both the ends in the X-axis direction (the vibrating arms 230 and 240) of the resonator element 200 increases. Therefore, when the resonator element 200 is mounted with the holding arm 250 fixed to the package, the resonator element 200 warps and the center of gravity G of the resonator element 200 moves to the package side (the lower side) with respect to the fulcrum P by the fixing. As a result, it is possible to improve stability of the resonator element 200 compared with the resonator element 200 having the relation of M1≦M2.

The mass M1 and the mass M2 only have to satisfy the relation of M1>M2. However, from the viewpoint of a balance of stability during mounting and a reduction in the size of the resonator element 200 and the like, M1/M2 is preferably equal to or larger than 1.1 and equal to or smaller than 1.6, more preferably equal to or larger than 1.2 and equal to or smaller than 1.5, and still more preferably equal to or larger than 1.3 and equal to or smaller than 1.4.

When the mass of the hammerheads 260 and 270 is represented as M3, a relation of M2<2×M3 is satisfied. Consequently, a warp of the resonator element 200 for displacing an end in the Y-axis direction (in particular, an end on the hammerheads 260 and 270 side) of the resonator element 200 to the lower side easily occurs. Therefore, when the resonator element 200 is mounted with the holding arm 250 fixed to the package, the center of gravity G of the resonator element 200 moves further to the package side (the lower side). As a result, it is possible to further improve the stability of the resonator element 200.

The mass M2 and the mass M3 only have to satisfy the relation of M2<2×M3 explained above. However, from the viewpoint that a warp of the resonator element 200 for displacing an end in the X-axis direction of the resonator element 200 to the lower side (the package side) more easily occurs, the relation of M2<M3 is preferably satisfied. Further, from the viewpoint of a balance of stability during mounting and a vibration characteristic of the resonator element 200 and the like, M3/M2 is preferably equal to or larger than 1.1 and equal to or smaller than 1.5, more preferably equal to or larger than 1.1 and equal to or smaller than 1.3, and still more preferably equal to or larger than 1.1 and equal to or smaller than 1.2.

Similarly, from the viewpoint that a warp of the resonator element 200 for displacing an end in the Y-axis direction (in particular, an end on the base section 220 side) of the resonator element 200 to the lower side (the package side) easily occurs, when the mass of the base section 220 is represented as M4, a relation of M2<M4 is satisfied.

The mass M2 and the mass M4 only have to satisfy the relation explained above. However, from the viewpoint of the balance of the stability during mounting and the vibration characteristic of the resonator element 200 and the like, M4/M2 is preferably equal to or larger than 1.1 and equal to or smaller than 1.5, more preferably equal to or larger than 1.1 and equal to or smaller than 1.3, and still more preferably equal to or larger than 1.1 and equal to or smaller than 1.2.

Concerning the mass M3 and the mass M4, from the viewpoint of the balance of the stability during mounting and the vibration characteristic of the resonator element 200 and the like, M3/M4 is preferably equal to or larger than 1.1 and equal to or smaller than 1.5, more preferably equal to or larger than 1.1 and equal to or smaller than 1.3, and still more preferably equal to or larger than 1.1 and equal to or smaller than 1.2.

Further, from the viewpoint that the warp of the resonator element 200 for displacing the end in the Y-axis direction (in particular, the end on the hammerheads 260 and 270 side) of the resonator element 200 to the lower side (the package side) easily occurs because of a warp of the arm sections 237 and 247 of the vibrating arms 230 and 240, when the mass of the arm sections 237 and 247 is represented as M5, a relation of M3>M5 is satisfied.

The mass M3 and the mass M5 only have to satisfy the relation explained above. However, from the viewpoint of the balance of the stability during mounting and the vibration characteristic of the resonator element 200 and the like, M3/M5 is preferably equal to or larger than 2.0 and equal to or smaller than 3.5, more preferably equal to or larger than 2.2 and equal to or smaller than 3.2, and still more preferably equal to or larger than 2.5 and equal to or smaller than 3.0.

Moreover, as explained above, the bottomed grooves 235, 236, 245, and 246 extending along the Y-axis direction are provided on the front and rear surfaces of the arm sections 237 and 247. Therefore, the arm sections 237 and 247 of the vibrating arms 230 and 240 easily warp. Consequently, the warp of the resonator element 200 for displacing the end in the Y-axis direction (in particular, the end on the hammerheads 260 and 270 side) of the resonator element 200 to the lower side (the package side) also easily occurs because of the warp of the arm sections 237 and 247 of the vibrating arms 230 and 240.

As explained above, the holding arm 250 connects the main body section 251 including the fixed section attached to the package and the connecting section 252 that connects the main body section 251 and the base section 220 and has width smaller than the width of the main body section 251. The warp of the resonator element 200 for displacing the end in the Y-axis direction (in particular, the end on the base section 220 side) of the resonator element 200 to the lower side (the package side) also easily occurs because of a warp of the holding arm 250.

According to the relation of the masses of the sections explained above, when the resonator element 200 is mounted with the holding arm 250 fixed to the package, the resonator element 200 warps, the center of gravity G of the resonator element 200 is located on the package side (the lower side) with respect to the fulcrum P by the fixing, and, as a result, it is possible to improve the stability of the resonator element 200.

For example, when the length along the Y-axis direction of the base section 220 is set to 90 μm, the length of the arm sections 237 and 247 of the vibrating arms 230 and 240 is set to 573 μm, the width of the arm sections 237 and 247 is set to 38 μm, the length along the Y-axis direction of the hammerheads 260 and 270 is set to 137 μm, the length along the X-axis direction of the hammerheads 260 and 270 is set to 255 μm, the width of the holding arm 250 is set to 100 μm, and the thickness of these sections (the thickness of the vibration substrate 210) is set to 130 μm, a relation of the masses of the sections is as explained below. It is possible to display the effects explained above.

In this case, the mass M1 of the vibrating arms 230 and 240 is 1.31 times as large as the mass M2 of the holding arm 250. The mass (2×M3) of the two hammerheads 260 and 270 is 1.94 times as large as the mass M2 of the holding arm 250. The mass M2 of the holding arm 250 is 1.18 times as large as the mass M4 of the base section 220. The mass M3 of the hammerheads 260 and 270 is 2.87 times as large as the mass M5 of the arm sections 237 and 247. The mass (2×M3) of the two hammerheads 260 and 270 is 2.29 times as large as the mass M4 of the base section 220.

As in this embodiment, when the two connection electrodes 331 and 332 included in the package and the two electrode pads provided in the holding arm 250 to respectively correspond to the two connection electrodes 331 and 332 are surely electrically connected by the conductive adhesive, it is possible to further reduce the likelihood of failure in the electric connection if the width of the holding arm 250 is set to 100 μm to increase the area of the holding arm 250.

On the other hand, when the stability during the mounting of the resonator element 200 on the package is prioritized to further keep the balance of the stability and the vibration characteristic of the resonator element 200, the width of the holding arm 250 only has to be set to 80 μm. In this case, the mass M1 of the vibrating arms 230 and 240 is 1.64 times as large as the mass M2 of the holding arm 250. The mass (2×M3) of the two hammerheads 260 and 270 is 2.43 times as large as the mass M2 of the holding arm 250. The mass M2 of the holding arm 250 is 0.94 times as large as the mass M4 of the base section 220. The mass M3 of the hammerheads 260 and 270 is 2.87 times as large as the mass M5 of the arm sections 237 and 247. The mass (2×M3) of the two hammerheads 260 and 270 is 2.29 times as large as the mass M4 of the base section 220.

The fixed section of the holding arm 250 includes, in plan view, the center of gravity G of a structure integrally formed including the base section 220, the vibrating arms 230 and 240, and the holding arm 250, that is, the resonator element 200 or the vibration substrate 210. Consequently, when the resonator element 200 is mounted with the holding arm 250 fixed to the package, it is possible to further improve the stability of the resonator element 200.

The distal end of the holding arm 250 is located further on the base section 220 side than the hammerheads 260 and 270. Consequently, it is possible to arrange the holding arm 250 efficiently using a space between the arms 237 and 247 of the pair of vibrating arms 230 and 240. Since the holding arm 250 is absent between the hammerheads 260 and 270 of the pair of vibrating arms 230 and 240, it is possible to reduce the distance between the vibrating arras 230 and 240. As a result, it is possible to attain a reduction in the size of the resonator element 200 (in particular, a reduction in the dimension in the X-axis direction).

### Second Embodiment

A second embodiment of the invention is explained.

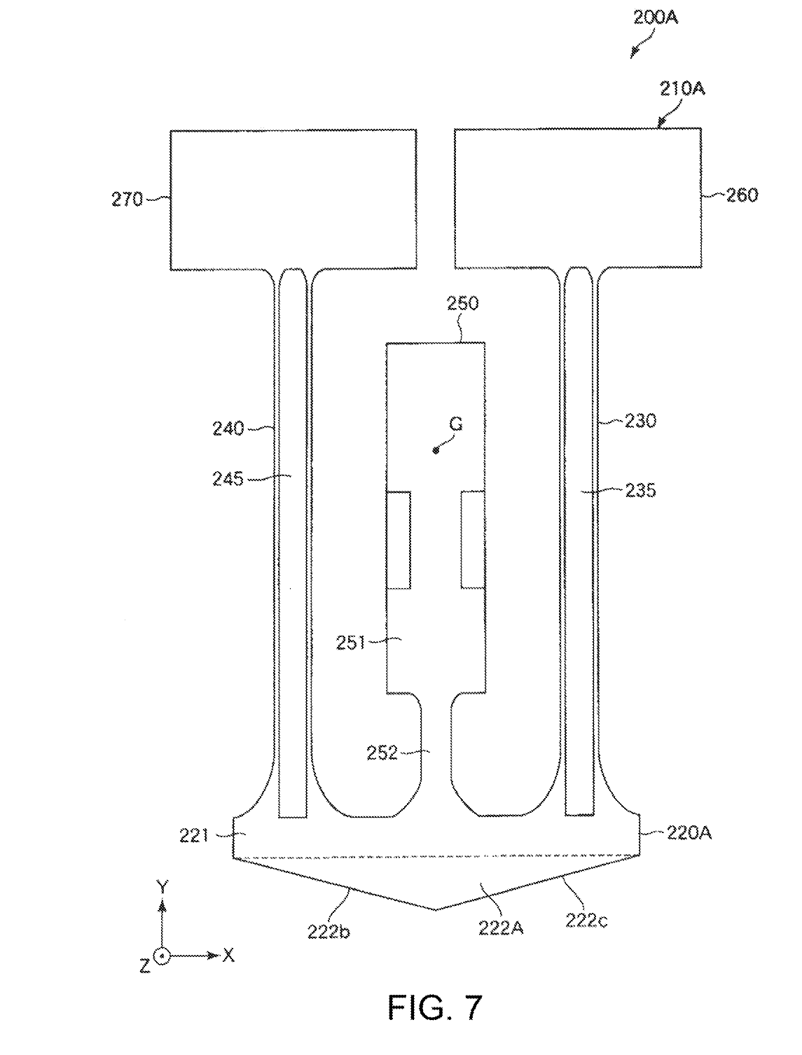

FIG. 7 is a plan view showing a resonator element according to the second embodiment of the invention.

In the following explanation, concerning the second embodiment, differences from the first embodiment are mainly explained. Explanation of similarities is omitted.

The second embodiment is the same as the first embodiment except that the configuration (the shape) of a reduced width section of a base section is different. Note that, in FIG. 7, components same as the components in the first embodiment are denoted by the same reference numerals and signs.

A base section 220A included in a resonator element 200A shown in FIG. 7 includes a reduced width section 222A. The contour of the reduced width section 222A is formed by linear inclined sections 222b and 222c inclined with respect to both of the X axis and the Y axis in plan view. One ends (ends in the −Y-axis direction side) of the inclined sections 222b and 222c are connected on the axis of symmetry Y1. That is, the inclined sections 222b and 222c are, for example, substantially in a symmetrical relation with respect to the axis of symmetry Y1 that passes the center between the vibrating arm 230 and the vibrating arm 240. Therefore, the reduced width section 222A has, at the distal end section thereof, an angle having the inclined sections 222b and 222c as sides and is sharp.

Note that an angle θ formed by the inclined sections 222b and 222c and the X axis is not particularly limited. However, from the viewpoint of suppressing an excessive increase in the size of the reduced width section 222A, the angle θ is preferably about equal to or larger than 5° and equal to or smaller than 70° and more preferably about equal to or larger than 10° and equal to or smaller than 50°.

When the vibration substrate 210A included in the base section 220 is patterned by wet-etching the quartz substrate, a crystal surface of quartz appears in the contour of the vibration substrate 210A. Therefore, if the inclined sections 222b and 222c parallel to the crystal surface are formed on a photomask and patterned, fluctuation in the shape decreases and stable performance can be obtained. In particular, it is desirable to set the inclined sections 222b and 222c parallel to a crystal surface formed at 30° or 60° with respect to the X axis of quartz.

The stability during setting can also be improved by the resonator element 200A according to the second embodiment explained above.

### 2. Resonator

A resonator applied with the resonator element according to the first embodiment of the invention (a resonator according to the first embodiment) is explained.

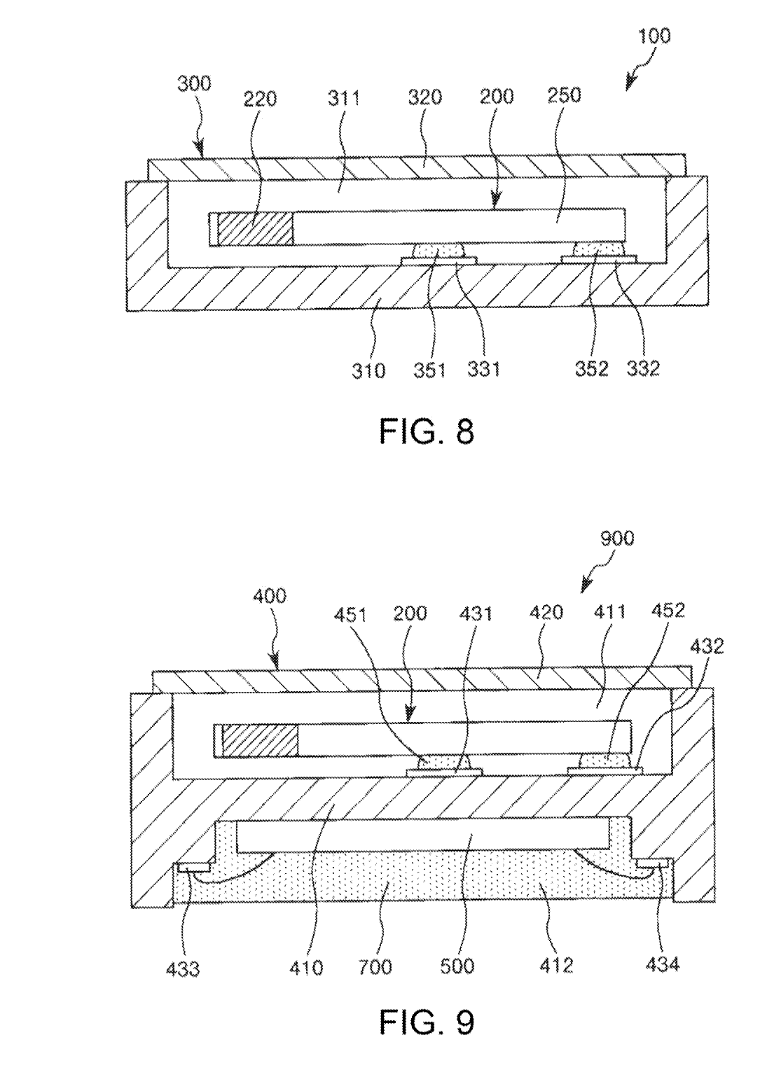

FIG. 8 is a diagram showing an example of the resonator according to the first embodiment.

A resonator 100 shown in FIG. 8 includes the resonator element 200 and the package 300 that houses the resonator element 200.

The package 300 includes a base substrate 310 of a cavity type including a recessed section 311 opened to the upper surface and a lid (a lid body) 320 joined to the base substrate 310 to cover an opening of the recessed section 311. The package 300 houses the resonator element 200 in an internal space thereof. The infernal space is hermetically formed.

The base substrate 310 is formed of a material having an insulation property. The material is not particularly limited. For example, various ceramics such as oxide-based ceramics, nitride-based ceramics, and carbide-based ceramics can be used. On the other hand, the lid 320 is formed of a member having a coefficient of linear expansion approximate to the coefficient of linear expansion of the constituent material of the base substrate 310. As such a material, for example, when the constituent, material of the base substrate 310 is the ceramics explained above, an alloy such as Kovar can be used.

The two connection electrodes 331 and 332 are formed on the bottom surface of the recessed section 311. The connection electrodes 331 and 332 are respectively electrically connected to not-shown mounted electrodes formed on the lower surface of the base substrate 310 via not-shown through-electrodes and not-shown inter-layer wires.

In the holding arm 250, the resonator element 200 housed in the housing space is supported on and fixed to the base substrate 310 via the pair of conductive adhesives 351 and 352 (fixing members) by the two fixing sections of the holding arm 250 (the fixing sections 251a and 251b). One conductive adhesive 351 is provided to electrically connect the connection electrode 331 and the first driving electrode 280. The other conductive adhesive 352 is provided to electrically connect the connection electrode 332 and the second driving electrode 290.

The resonator element 200 can be driven by an input of a driving signal via the two conductive adhesives 351 and 352. Note that metal bumps may be used instead of the conductive adhesives 351 and 352.

The resonator explained above includes the resonator element 200 excellent in the stability during setting. Therefore, the resonator can be easily set such that the resonator element 200 is parallel to the base substrate 310. As a result, the resonator has high yield during manufacturing and excellent reliability.

### 3. Oscillator

An example of an oscillator applied with the resonator element according to the first embodiment of the invention (an oscillator according to the first embodiment) is explained.

FIG. 9 is a diagram showing an example of the oscillator according to the first embodiment.

An oscillator 900 shown in FIG. 9 includes the resonator element 200, a package 400 that houses the resonator element 200, and an IC chip (a chip component) 500 for driving the resonator element 200.

The package 400 includes a base substrate 410 and a lid (a lid body) 420 joined to the base substrate 410.

The base substrate 410 includes a first recessed section 411 opened to the upper surface and a second recessed section 412 opened to the lower surface.

An opening of the first recessed section 411 is closed by the lid 420. The resonator element 200 is housed or the inner side of the lid 420. Two connection electrodes 431 and 432 are formed in the first recessed section 411. In the holding arm 250, the resonator element 200 in the first recessed section 411 is supported by and fixed to the base substrate 410 via a pair of conductive adhesives 451 and 452. One conductive adhesive 451 is provided to electrically connect the connection electrode 431 and the first driving electrode 280. The other conductive adhesive 452 is provided to electrically connect the connection electrode 432 and the second driving electrode 290.

On the other hand, the IC chip 500 is housed in the second recessed section 412. The IC chip 500 is fixed to the base substrate 410 via an adhesive. At least two IC connection electrodes 433 and 434 are formed in the second recessed section 412. The IC connection electrode 433 is electrically connected to the IC chip 500 by a bonding wire and electrically connected to the connection electrode 431 via a not-shown through electrode and a not-shown inter-layer wire. Similarly, the IC connection electrode 434 is electrically connected to the IC chip 500 by a bonding wire and electrically connected to the connection electrode 432 via a not-shown through electrode and a not-shown inter-layer wire. A sealing material 700 formed of a resin composition is filled in the second recessed section 412. The IC chip 500 is sealed by the sealing material 700.

The IC chip 500 includes a driving circuit (an oscillating circuit) for controlling driving of the resonator element 200. When the resonator element 200 is driven by the IC chip 500, it is possible to extract a signal having a predetermined frequency.

The oscillator explained above includes the resonator element 200 excellent in the stability during setting. Therefore, the oscillator can be easily set such that the resonator element 200 is parallel to the base substrate 410. As a result, the oscillator has nigh yield during manufacturing and excellent reliability.

### 4. Electronic Device

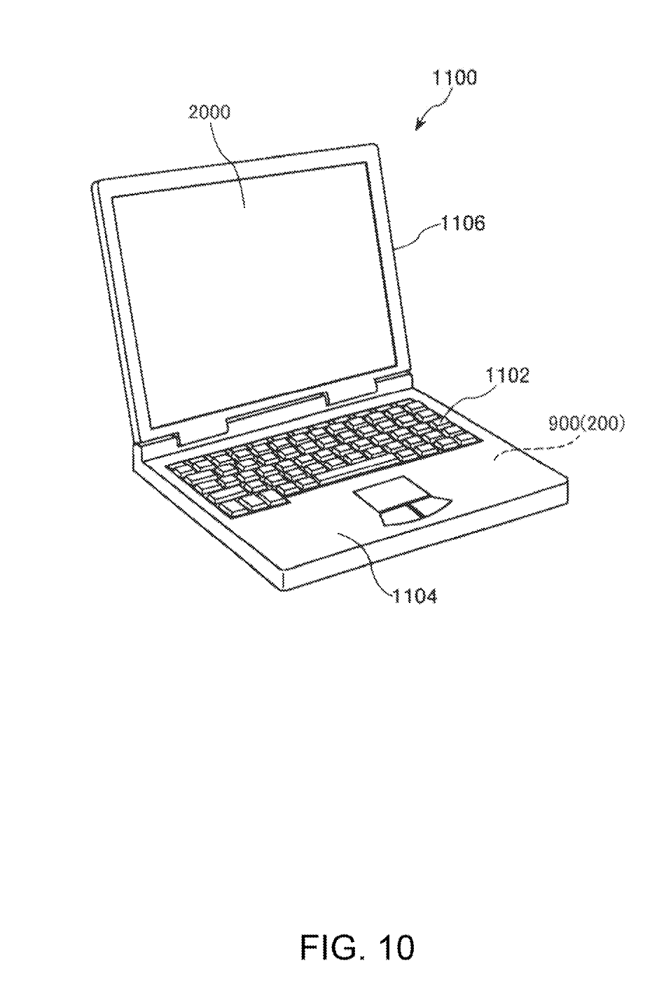

An electronic device applied with the resonator element according to the first embodiment of the invention (an electronic device according to the first embodiment) is explained in detail with reference to FIGS. 10 to 12.

FIG. 10 is a perspective view showing the configuration of a personal computer of a mobile type (or a notebook type), which is a first example of the electronic device according to the first embodiment. In the figure, a personal computer 1100 is configured by a main body section 1104 including a keyboard 1102 and a display unit 1106 including a display section 2000. The display unit 1106 is turnably supported with respect to the main body section 1104 via a hinge structure section. The personal computer 1100 incorporates the oscillator 900 (the resonator element 200).

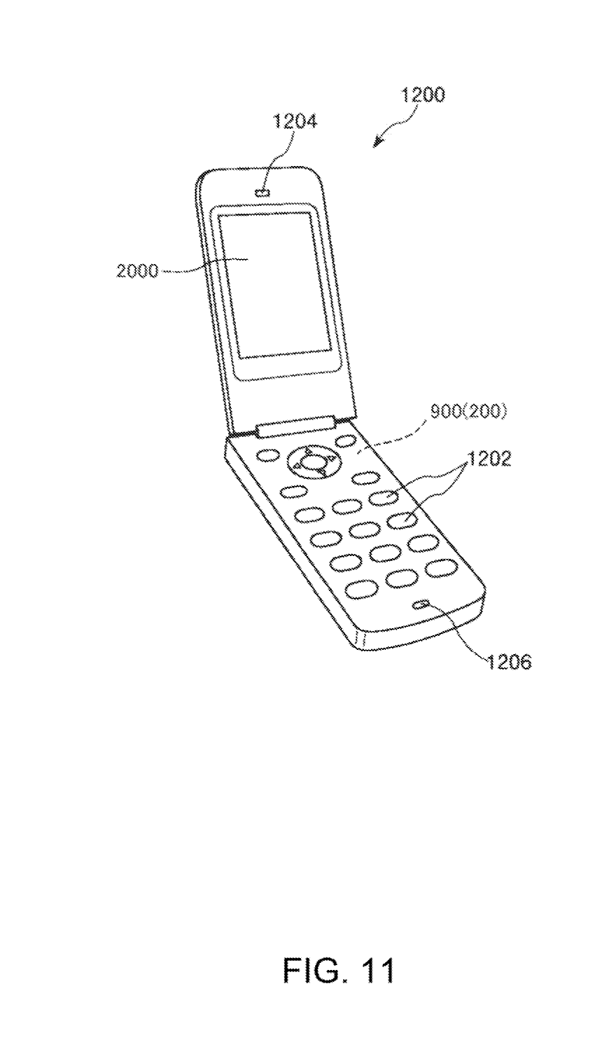

FIG. 11 is a perspective view showing the configuration of a cellular phone (including a PHS), which is a second example of the electronic device according to the first embodiment. In the figure, a cellular phone 1200 includes a plurality of operation buttons 1202, an earpiece 1204, and a mouthpiece 1206. A display section 2000 is arranged between the operation buttons 1202 and the earpiece 1204. The cellular phone 1200 incorporates the oscillator 900 (the resonator element 200).

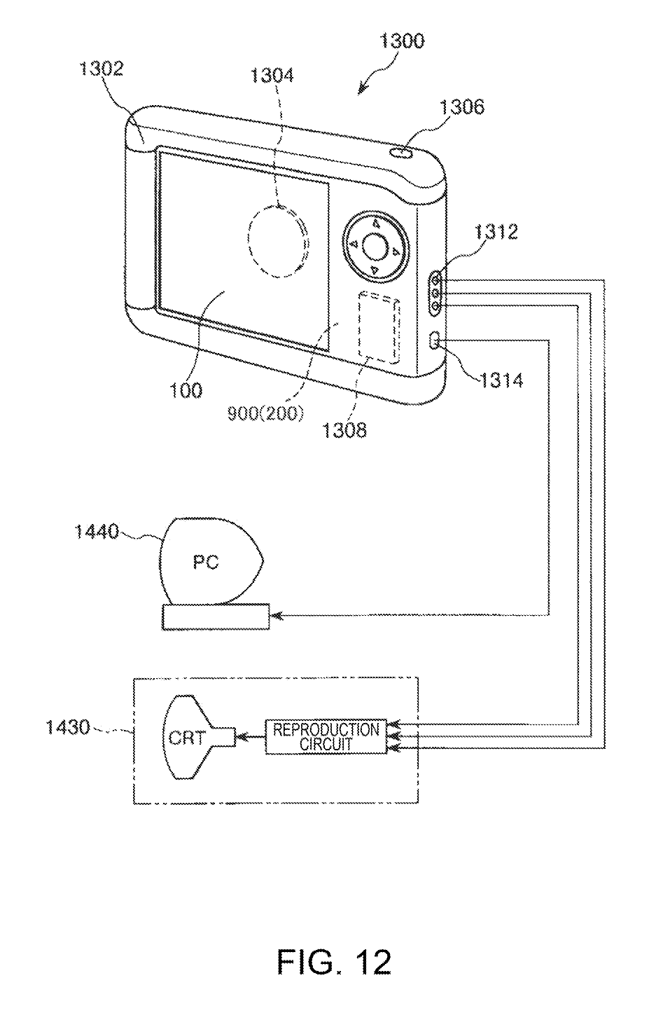

FIG. 12 is a perspective view showing the configuration of a digital still camera, which is a third example of the electronic device according to the first embodiment. Note that, in the figure, connection to external apparatuses is simply shown. Whereas a normal camera exposes a silver halide photograph film to an optical image of an object, a digital still camera 1300 photoelectrically converts an optical image of an object with an image pickup device such as a CCD (Chare Coupled Device) and generates an image pickup signal (an image signal).

A display section is provided on the rear surface of a case (a body) 1302 in the digital still camera 1300, and display is performed on the basis of the image pickup signal by CCD. The display section functions as a finder that displays an object as an electronic image. On the front side (the rear surface side in the figure) of the case 1302, a light receiving unit 1304 including an optical lens (an image pickup optical system) and a CCD is provided.

When a photographer checks an object image displayed on the display section and depresses a shutter button 1306, an image pickup signal of the CCD at that point is transferred to and stored in a memory 1308. In the digital still camera 1300, a video signal output terminal 1312 and an input and output terminal 1314 for data communication are provided on a side surface of the case 1302. As shown in the figure, a television monitor 1430 is connected to the video signal output terminal 1312 according to necessity. A personal computer 1440 is connected to the input and output terminal 1314 for data communication according to necessity. Further, the image pickup signal stored in the memory 1308 is output to the television monitor 1430 and the personal computer 1440 by predetermined operation. The digital still camera 1300 incorporates the oscillator 900 (the resonator element 200).

The electronic devices explained above have excellent reliability.

Note that, the electronic device including the resonator element according to the first embodiment of the invention can be applied to, besides the personal computer (the mobile personal computer) shown in FIG. 10, the cellular phone shown in FIG. 11, and the digital still camera shown in FIG. 12, for example, an inkjet discharge apparatus (e.g., an inkjet printer), a laptop personal computer, a television, a video camera, a video tape recorder, a car navigation apparatus, a pager, an electronic organizer (including an electronic organizer with a communication function), an electronic dictionary, an electronic calculator, an electronic game machine, a word processor, a work station, a videophone, a television monitor for crime prevention, electronic binoculars, a POS terminal, medical equipment (e.g., an electronic thermometer, a blood pressure manometer, a blood sugar meter, an electrocardiogram measuring apparatus, an ultrasonic diagnostic apparatus, and an electronic endoscope), a fish finder, measurement instruments, meters (e.g., meters of a vehicle, an airplane, and a ship), a flight simulator, and the like.

### 5. Mobile Object

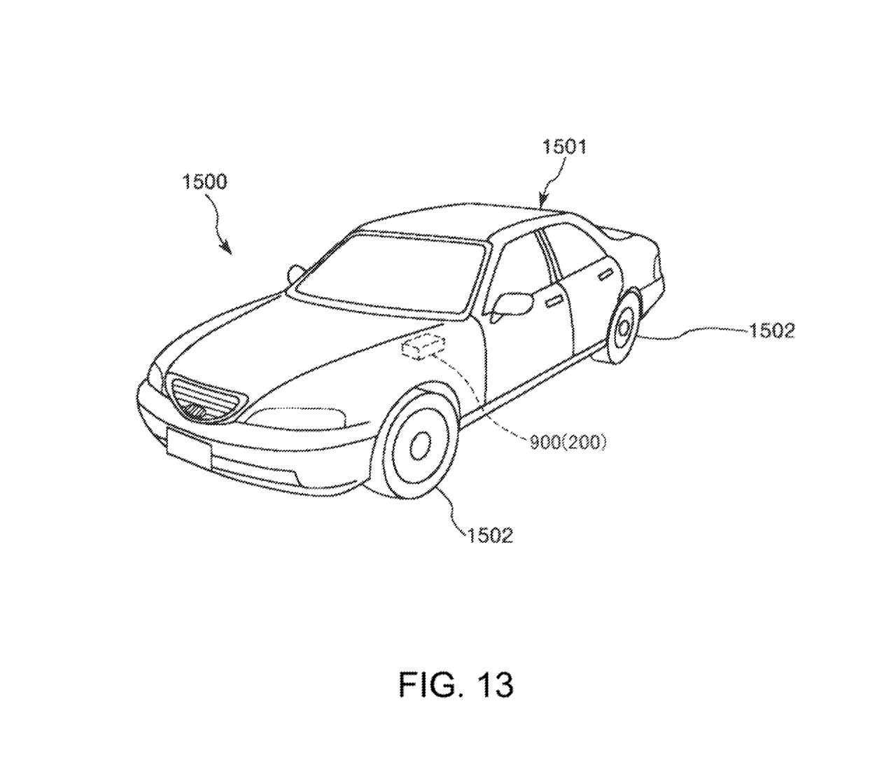

FIG. 13 is a perspective view showing the configuration of an automobile, which is an example of a mobile object according to the first embodiment of the invention. In the figure, a mobile object 1500 includes a vehicle body 1501 and four wheels 1502. The mobile object 1500 is configured to rotate the wheels 1502 with a not-shown power source (an engine) provided in the vehicle body 1501. The mobile object 1500 incorporates the oscillator 900 (the resonator element 200).

The mobile object explained above has excellent reliability. Mote that the mobile object according to the first embodiment is not limited to the automobile and can be applied to various mobile objects such as an airplane, a ship, and a motor cycle.

The resonator element, the resonator, the oscillator, the electronic device, and the mobile object according to the first and second embodiments of the invention are explained above. However, the invention is not limited to the embodiments. The components of sections can be replaced with any components having the same functions. Any other components may be added to the invention.

Projecting sections or hollows (cutouts) may be formed in the contour of the reduced width section in the embodiments.

In the example explained in the embodiments, the thickness of the vibration substrate is fixed over the entire area. However, the vibration substrate may include a portion having different thickness. For example, the thickness of the connecting section of the holding arm may be smaller than the thickness of the main body section of the holding arm.

The entire disclosure of Japanese Patent Application No. 2013-237474, filed Nov. 16, 2013 is expressly incorporated by reference herein.

What is claimed is:

1. A resonator element comprising:
a base section;
a pair of vibrating arms extending from the base section along a first direction and arranged side by side along a second direction, which crosses the first direction, in plan view; and
a holding arm arranged between the pair of vibrating arms and extending from the base section along the first direction in plan view, wherein
when mass of each of the pair of vibrating arms is represented as M1 and mass of the holding arm is represented as M2, a relation of M1>M2 is satisfied.

2. The resonator element according to claim 1, wherein
the vibrating arm includes:
a weight section; and
an arm section arranged between the base section and the weight section in plan view, and
when mass of the weight section is represented as M3, a relation of M2<2×M3 is satisfied.

3. The resonator element according to claim 2, wherein a relation of M2<M3 is satisfied.

4. The resonator element according to claim 3, wherein, when mass of the base section is represented as M4, a relation of M2<M4 is satisfied.

5. The resonator element according to claim 4, wherein, when mass of the arm section is represented as M5, a relation of M3>M5 is satisfied.

6. The resonator element according to claim 1, wherein
a fixed section attached to a target object is provided in the holding arm, and
the fixed section overlaps a center of gravity of a structure including the base section, the vibrating arm, and the holding arm in plan view.

7. The resonator element according to claim 2, wherein a distal end of the holding arm on an opposite side of the base section side is located further on the base section side than the weight section.

8. The resonator element according to claim 1, wherein the holding arm includes:
a main body section including a fixed section attached to a target object; and
a connecting section that connects the main body section and the base section and has width along the second direction smaller than width of the main body section.

9. The resonator element according to claim 1, wherein a groove is provided along the first direction on at least one of a first principal plane and a second principal plane of the arm section that are in a front-back relation to each other.

10. A resonator comprising:
the resonator element according to claim 1; and
a package in which the resonator element is housed.

11. An oscillator comprising:
the resonator element according to claim 1; and
an oscillation circuit electrically connected to the resonator element.

12. An electronic device comprising the resonator element according to claim 1.

13. A mobile object comprising the resonator element according to claim 1.
